(19) United States
(12) Patent Application Publication
(10) Pub. No.: US 2025/0293701 A1
(43) Pub. Date: Sep. 18, 2025

(54) Digital finite impulse response filtering method and associated filtering device

(71) Applicant: THALES, Meudon (FR)

(72) Inventors: Patrick DERVIN, MERIGNAC (FR); François ROBERT, MERIGNAC (FR); Frédéric CAUDOUX, MERIGNAC (FR); Stéphane BOUYAT, MERIGNAC (FR)

(21) Appl. No.: 19/080,128

(22) Filed: Mar. 14, 2025

(30) Foreign Application Priority Data
Mar. 14, 2024 (FR) 2402558

(51) Int. Cl. H03M 1/06; G04F 10/00

(52) U.S. Cl. CPC H03M 1/0626; G04F 10/00

(57) ABSTRACT

The present invention relates to a finite impulse response filtering method, including acquisition of a digital signal corresponding to an analog signal converted by an analog/digital converter, application of a digital processing to the digital signal in order to transform the signal into a sum of a time-variable part and a time-constant part, removal of the variable part of the transformed digital signal so as to obtain a constant digital signal, by applying a sequence of a plurality of sinusoidal band-stop filters, digital processing of the constant digital signal so as to obtain an amplitude of the signal, and transmission of the amplitude to an application software.

### REFERENCE TO RELATED APPLICATION

This application is a U.S. non-provisional application claiming the benefit of French Patent Application No. 24 03558 filed on Mar. 14, 2024, the contents of which are incorporated herein by reference in their entirety.

### TECHNICAL FIELD OF THE INVENTION

The present invention relates to a finite impulse response filtering method. The present invention further relates to a filtering device associated with such method.

### BACKGROUND OF THE INVENTION

In avionics, in order to ensure the safety of the systems, it is necessary to use sensors to estimate values such as position.

The useful signals acquired by sensors for avionics systems are converted into digital form for the computer processing thereof.

Often, it is necessary to pick up not only the useful content of the digital signals but also to eliminate the so-called alternative components, which vary over time. Such components may come from noise picked up as well as from processing applied to the signals.

To remove unwanted components, different methods of filtering problematic frequency ranges are generally used.

The filtering methods of the prior art use digital filters from two main classes: Finite Impulse Response (FIR) filters and Infinite Impulse Response (IIR) filters. The two types mentioned have advantages and disadvantages, but both are widely used in avionics.

IIR filters are filters that require few calculation coefficients and operations but because of the structure thereof, do not have a rapid recovery after a disturbance and often have a high latency.

FIR filters are most often used for several reasons which include the deterministic and robust side thereof, in addition to the ability thereof to recover following a disturbance while keeping a low latency.

However, it is known that FIR filters require considerable computation resources and have a high economic cost.

### SUMMARY OF THE INVENTION

There is thus a need for finite impulse response filtering which would be less expensive and needing less computational resources than the current technologies.

To this end, the subject matter of the present is a finite impulse response filtering method including:
acquisition of a digital signal corresponding to an analog signal converted by an analog/digital converter;
application of a digital processing to the digital signal in order to transform the signal into a sum of a part variable in time and a part constant in time;
removal of the variable part of the transformed digital signal so as to obtain a constant digital signal, by applying a sequence of a plurality of sinusoidal band-stop filters;
digital processing of the constant digital signal so as to obtain an amplitude of the signal;
transmission of the amplitude to an application software.

According to other advantageous aspects of the invention, the method includes one or a plurality of the following features, taken individually or according to all possible:
the plurality of sinusoidal band-stop filters includes between 2 and 20 sinusoidal band-stop filters, advantageously between 4 and 10 sinusoidal band-stop filters;
the number of band-stop filters in the plurality of sinusoidal band-stop filters is chosen depending on a frequency range of the digital signal;
each sinusoidal band-stop filter has a plurality of configuration parameters enabling same to be configured; advantageously, each sinusoidal band-stop filter has two configuration parameters;
each sinusoidal band-stop filter has at least a first configuration parameter corresponding to a main cut-off frequency and a second configuration parameter corresponding to a spacing of the filter;
the sinusoidal band-stop filters of the plurality of sinusoidal band-stop filters have different configuration parameters;
the configuration parameters of the different sinusoidal band-stop filters are chosen so that the cut-off frequencies of certain filters correspond substantially to the band-pass frequencies of the other filters;
the removal further includes an application of one or a plurality of moving averages to the digital signal resulting from the sequence of the plurality of sinusoidal band-stop filters;
the analog signal comes from an avionics sensor and wherein the application software is an avionics software;
the digital processing further includes determination of a phase of the constant signal.

A further subject matter of the invention relates to a finite impulse response filtering device, including technical means configured for implementing the method as defined hereinabove.

### BRIEF DESCRIPTION OF THE DRAWINGS

The invention will be clearer upon reading the following description, given only as an example, but not limited to, and making reference to the drawings wherein:

FIG. 1 is a view of an acquisition architecture for analog signals including a filtering device according to the invention;

FIG. 2 is a detailed view of the interaction device shown in FIG. 1;

FIG. 3 is an organization chart of a detection method according to the invention, the method being implemented by the device shown in FIG. 2; and

FIGS. 4 to 10 are different illustrations of the implementation of at least certain operations of the method shown in FIG. 3.

### DETAILED DESCRIPTION OF THE INVENTION

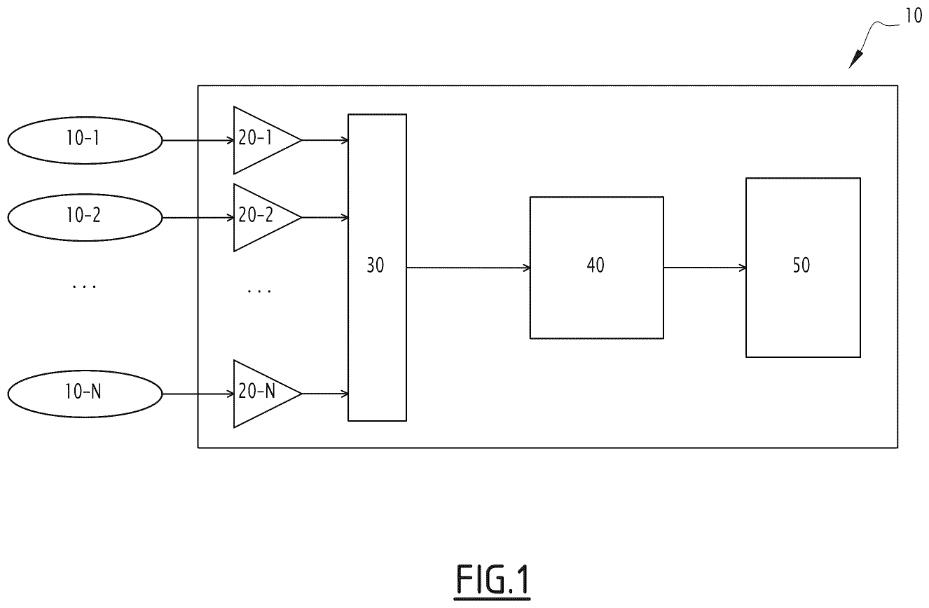

FIG. 1 illustrates an acquisition architecture 10 for analog signals, which may be used, e.g., in the field of avionics. The architecture 10 makes it possible to convert analog signals into digital signals and to transmit the latter to one or a plurality of avionics applications.

According to other embodiments, the acquisition architecture 10 may be used in any other field implementing a conversion of analog signals into digital signals.

With reference to FIG. 1, the acquisition architecture 10 includes a set of sensors 10-1, . . . , 10-N, a set of signal conditioners 20-1, . . . , 20-N, an analog-to-digital converter 30, a filtering device 40 and one or a plurality of software packages 50.

The number of sensors 10-1, . . . , 10-N is N (N>0) and same are, e.g., avionics sensors of the same nature or of different natures. Each sensor 10-1, . . . , 10-N is configured more particularly to measure at least one physical quantity or to receive external signals, and to generate analog signals from the measurement or from external signals. Thereby, each sensor 10-1, . . . , 10-N corresponds, e.g., to a position, pressure, speed, temperature sensor, or e.g. to a GNSS (Global Navigation Satellite

Systems) signal sensor or to any other signal relating to the position of the aircraft. When a position sensor is involved, same may correspond to an electromagnetic sensor, e.g., a linear sensor such as an LVDT (Linear Variable Differential Transformer), a rotary sensor such as an RVDT (Rotary Variable Differential Transformer), a resolver rotary sensor resolver or a SYNCHRO rotary sensor.

Advantageously, each sensor 10-1, . . . , 10-N is arranged outside the aircraft, e.g., on the fuselage of the aircraft.

The signal conditioners 20-1, . . . , 20-N, the number of which depends on the number of sensors 10-1, . . . , 10-N, are connected to the latter and serve, e.g., to amplify and/or shape the analog signals acquired by the sensors 10-1, . . . , 10-N. Advantageously, there are N conditioners 20-1, . . . , 20-N, just like the sensors 10-1, . . . , 10-N. Thereby, each conditioner 20-1, . . . , 20-N is connected to a respective sensor 10-1, . . . , 10-N.

The analog-to-digital converter 30 is connected to all signal conditioners 20-1, . . . , 20-N and is used to convert analog signals coming from conditioners 20-1, . . . , 20-N into digital signals. Such a converter 30 is known, e.g., under the abbreviation ADC (Analog-to-Digital Converter).

The or each piece of software 50 has, e.g., an avionics application connected to the filtering device 40. Such software 50 is configured to receive digital signals from the filtering device 40 and to process same according to the nature of the sensor 10-1, . . . , 10-N corresponding to such signals. For example, such a software 50 is configured to deduce the position of the aircraft from the signals acquired when the signals correspond to GNSS signals and/or come from one or a plurality of position sensors, to display and/or communicate to any interested system, the position and/or the speed of the aircraft.

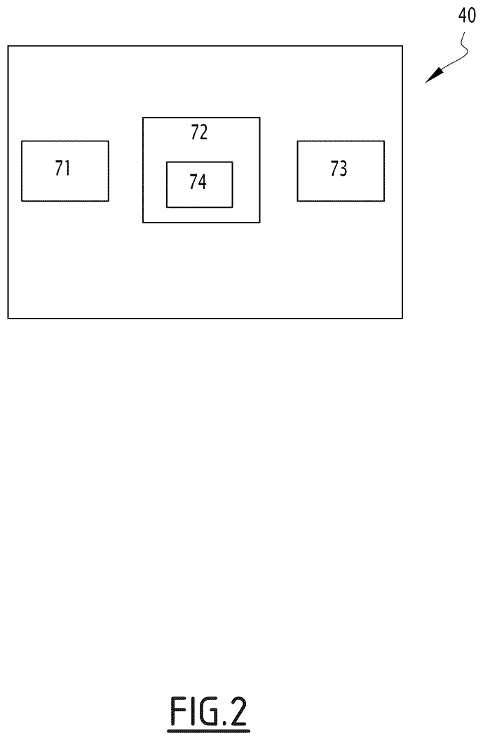

The filtering device 40 is shown in more detail in FIG. 2. The filtering device 40 is, e.g., implemented at least partially in the form of one or a plurality of programmable logic circuits such as FPGA (Field Programmable Gate Array). In addition or as a variant, the filtering device 40 is implemented at least partially in the form of one and a plurality of software programs. In such case, the software is stored in a suitable memory and may be executed by one or a plurality of processors.

With reference to FIG. 2, the filtering device 40 includes an input module 71, a processing module 72 and an output module 73.

The input module 71 serves to receive the digital signals converted by the analog-to-digital converter 30.

The processing module 72 serves to process the converted digital signals in order to remove the variable part thereof in time. More particularly, to this end, the processing module 72 includes a low-pass filtering unit 74 configured to apply a sinusoidal band-stop filter, as will be explained in greater detail hereinafter.

Finally, the output module 73 serves to transmit the signals processed by the processing module 72 to one or a plurality of software programs 50.

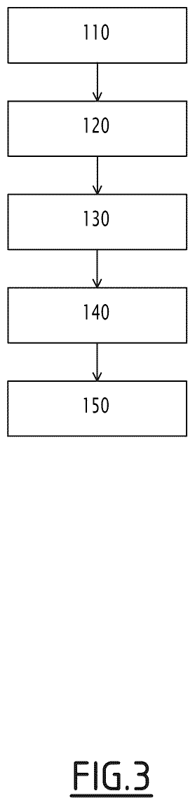

The filtering device 40 serves to implement a filtering method which will henceforth be explained with reference to FIG. 3 which shows an organization chart of the operations thereof.

It is initially considered that sensors 10-1, . . . , 10-N are in operation and acquire corresponding measurements/signals in the form of analog signals. Furthermore, it is considered that the analog signals have a sinusoidal shape and contain useful information in the amplitude of the sinusoidal shape and possibly in the phase thereof. More particularly, it is considered that each acquired signal f(t) has the following form:

$$f ( t ) = A * sin ( 2 π Ft + φ )$$

where
A is the amplitude of the signal and thus corresponds to the useful information of the signal,
F is the frequency of the signal, and
φ is the phase at the origin of the signal.

The conditioners 20-1, . . . , 20-N shape and, if appropriate, amplify the corresponding analog signals and transmit same to the analog-to-digital converter 30. The converter 30 then converts the analog signals into corresponding digital signals.

During an initial operation 110, the input module 71 acquires the digital signals converted by the analog-to-digital converter 30.

During a next operation 120, the processing module 72 applies a digital processing to each digital signal acquired by the input module 71 in order to transform the signal into a sum of a part variable in time and a part constant in time.

An example of implementation of operation 120 is illustrated in

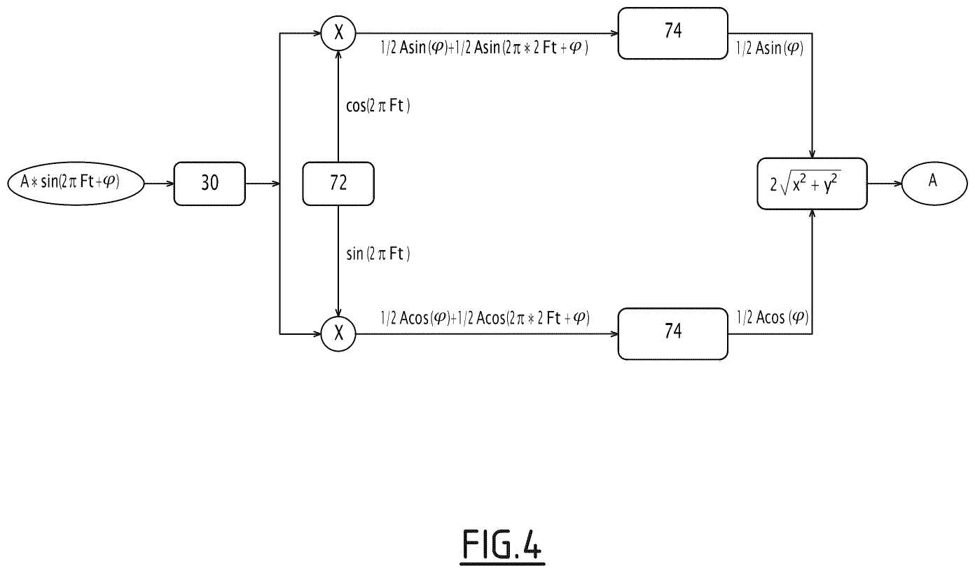

FIG. 4. According to such example, the processing module 72 implements a technique known as “synchronous demodulation”.

According to such technique, the processing module 72 divides the acquired digital signal into two identical signals and multiplies each signal obtained by a sinusoidal function having the same time-dependent part as the acquired digital signal.

More particularly, as shown in FIG. 4, the processing module 72 divides the acquired signal f(t)=A*sin(2πFt+φ) into two identical parts and multiplies each of the parts by sin(2πFt) and cos(2πFt), respectively, in order to obtain two following intermediate signals:

$$Y ( t ) = f ( t ) * cos ( 2 π Ft ) = \frac{1}{2} * A * sin ( φ ) + \frac{1}{2} * A * sin ( 2 * 2 π Ft + φ ) ;$$

$$X ( t ) = f ( t ) * cos ( 2 π Ft ) = \frac{1}{2} * A * cos ( φ ) + \frac{1}{2} * A * cos ( 2 * 2 π Ft + φ ) .$$

Each intermediate signal thereby has a sum of a part variable in time and a part constant in time.

During a next operation 130, the low-pass filtering unit 74 applies a filtering to each intermediate signal in order to remove the part thereof variable in time.

Indeed, by denoting by H(f) the filtering function applied by the filtering unit 74, the low-pass filtering unit 74 obtains at the output the filtered intermediate signals:

$$s ( A , φ ) = Y ( f ) * H ( f ) = \frac{1}{2} * A * sin ( φ ) ;$$

$$c ( A , φ ) = X ( f ) * H ( f ) = \frac{1}{2} * A * cos ( φ ) ;$$

which are constant over time and no longer depend on the frequency F.

During a next operation 140, the processing module 72 removes the phase of φ each filtered signal to keep only the amplitude A thereof.

As shown in FIG. 4, to this end, the processing module 72 may add the squares of the filtered intermediate signals so that:

$$A = 2 \sqrt{{s ( A , φ )}^{2} + {c ( A , φ )}^{2}} .$$

Optionally, during this operation, the processing module 72 also calculates the phase φ.

During a subsequent operation 150, the output module 73 transmits the amplitude A and, if appropriate, the phase φ to one or a plurality of avionics software programs 50.

According to the invention, in order to remove the part variable in time during operation 130, the low-pass filtering unit 74 applies a FIR (Finite Impulse Response) filtering which has a sequence of a plurality of sinusoidal band-stop filters.

“Sequence of a plurality of filters” refers to a sequential application of the filters so that each subsequent filter (except the first filter) is applied to the output of the preceding filter. The first filter is applied to the initial function.

“Sinusoidal band-stop filter”, also called a CBS filter, refers to a digital filter such as FIR the curve of which of the gain as a function of the frequency is a sinusoidal function of the frequency.

More particularly, in the case of a sinusoidal band-stop filter, the gain curve G(f) thereof is a sinusoidal function of frequency.

The response y(n) of such a filter is written in the following form:

$$y ( n ) = K G * ( x ( n - 2 e ) + K F C * x ( n - e ) + x ( n ) )$$

$$with :$$

$$KFC = - cos ( \frac{2 π {F}_{c}}{{F}_{s}} * e ) ;$$

$$KG = \frac{1}{1 + K F C + 1}$$

where:
F_{c} is the main cut-off frequency,
Fₛ is the sampling frequency of the signal,
e is the spacing of the filter, and
x(n) are different samples of the input signal.

The sampling frequency Fₛ is imposed during acquisition.

As indicated hereinabove, the coefficients KFC and KG may be directly deduced from the values F_{c}, Fₛ and e.

The main cut-off frequency F_{c} and the spacing of the filter e are

two separate parameters of each sinusoidal band-stop filter. The parameters thus form configuration parameters of each filter.

Each CBS filter advantageously has a plurality of cut-off frequencies, i.e., a plurality of frequencies wherein the function of the gain of the filter is equal to 0.

Moreover, each CBS filter has a plurality of passband frequencies, i.e., a plurality of frequencies wherein the function of the gain of the filter is equal to 1.

According to the invention, the parameters F_{c} and e are chosen for each CBS filter in the sequence of the CBS filters as a function of the cut-off and passband frequencies desired for the CBS filter.

In particular, the parameters F_{c} and e are chosen for the CBS filters in such a way that the cut-off frequencies of certain filters correspond to the passband frequencies of the other filters. Such correspondence may be exact or approximate.

To this end, e.g., it may be considered that the sequence of the CBS filters includes a first subset of CBS filters and a second subset of CBS filters.

In such a case, the parameters F_{c} and e of the first subset of filters may be chosen so as to define a plurality of predetermined cut-off frequencies and the parameters F_{c} and e of the second subset may be chosen so as to define a plurality of cut-off frequencies corresponding to the passband frequencies of the CBS filters of the first subset.

In other words, the parameters F_{c} and e of the first subset of filters are chosen to create well-determined cut-off frequencies, and the parameters F_{c} and e of the second subset are chosen to remove what the first subset of filters let pass, so as to create a global low-pass filtering in addition to the clear cutoffs.

Similarly, the parameters F_{c} and e of the second subset of the CBS filters may be chosen so as to define a plurality of predetermined cut-off frequencies and the parameters F_{c} and e of the first subset of the CBS filters may be chosen so as to define a plurality of passband frequencies corresponding to the cut-off frequencies of the CBS filters of the second subset.

Of course, other techniques of choice of parameters F_{c} and e may still be used in order to obtain a resulting response almost-zero except in 0. Thereof then produces a low-pass filter in addition to the clear cutoffs.

Advantageously, the number of CBS filters in the sequence of filters is greater than or equal to 2. The number may include, e.g., between 2 and 15, preferably between 2 and 10, and may be equal in some examples to 2, 3, 4, 5, 6 or 7.

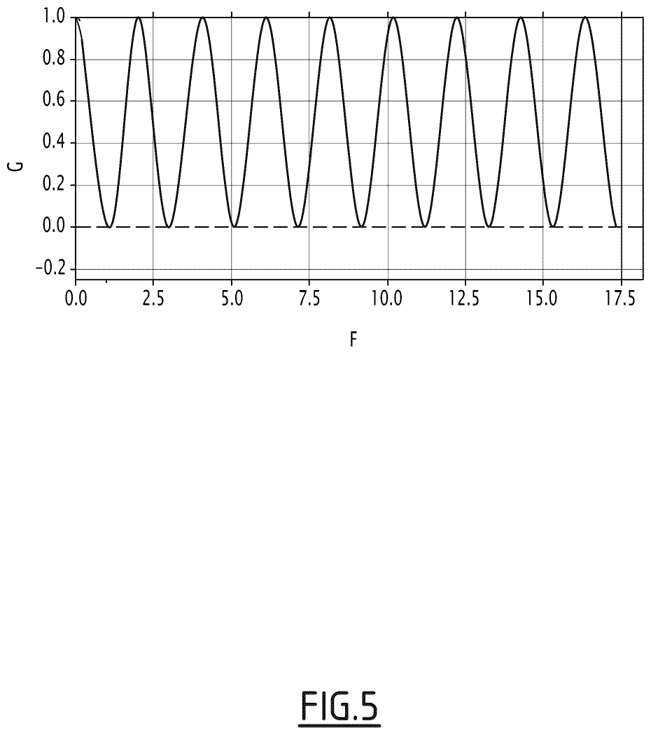

FIGS. 5 to 10 illustrate an example of applying a sequence of CBS filter with different numbers of filters.

More particularly, FIG. 5 illustrates the output of the first CBS filter in the sequence of CBS filters. Such output has a sinusoidal function with a plurality of cut-off frequencies and a plurality of passband frequencies.

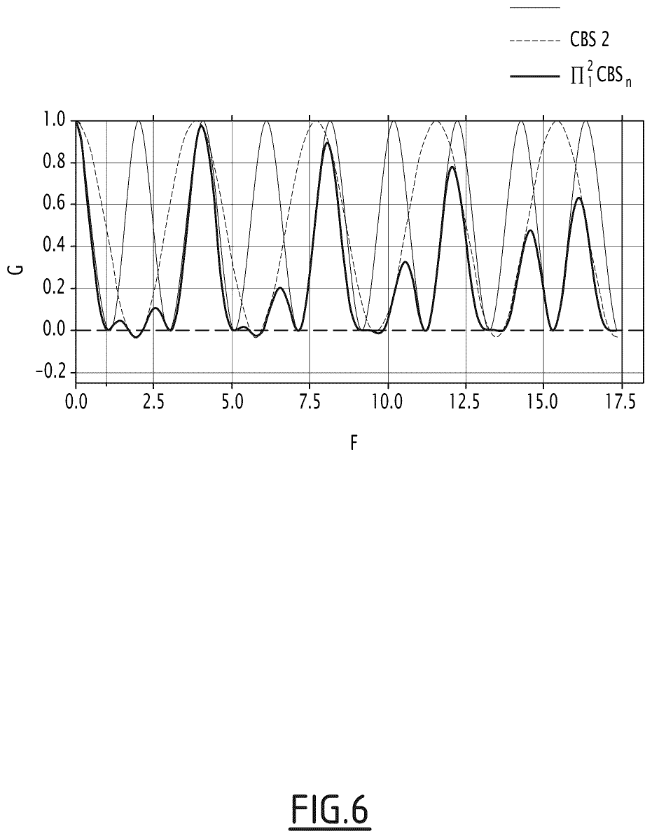

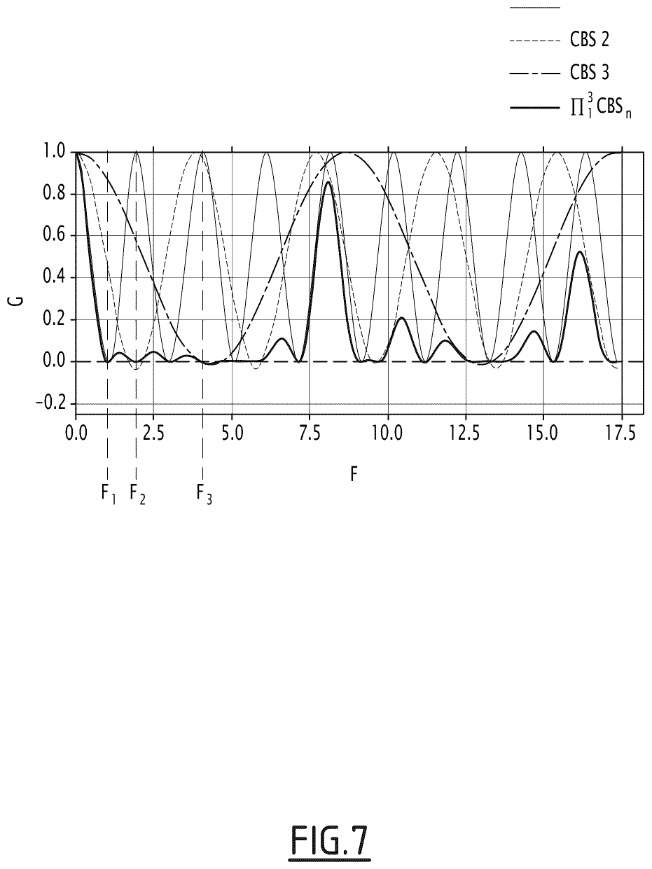

FIGS. 6 and 7 illustrate individual responses of two CBS filters (CBS 1, CBS 2) and of three CBS filters (CBS 1, CBS 2, CBS 3), respectively. The figures also illustrate the resultant function Π CBS corresponding to the product of the individual responses (i.e., resulting function after the sequence of two or three CBS filters).

As may be seen in FIG. 7, the resulting function of the three CBS filters (CBS 1, CBS 2, CBS 3) generates at least three sharp cut-offs, in particular in the points F₁, F₂ and F₃.

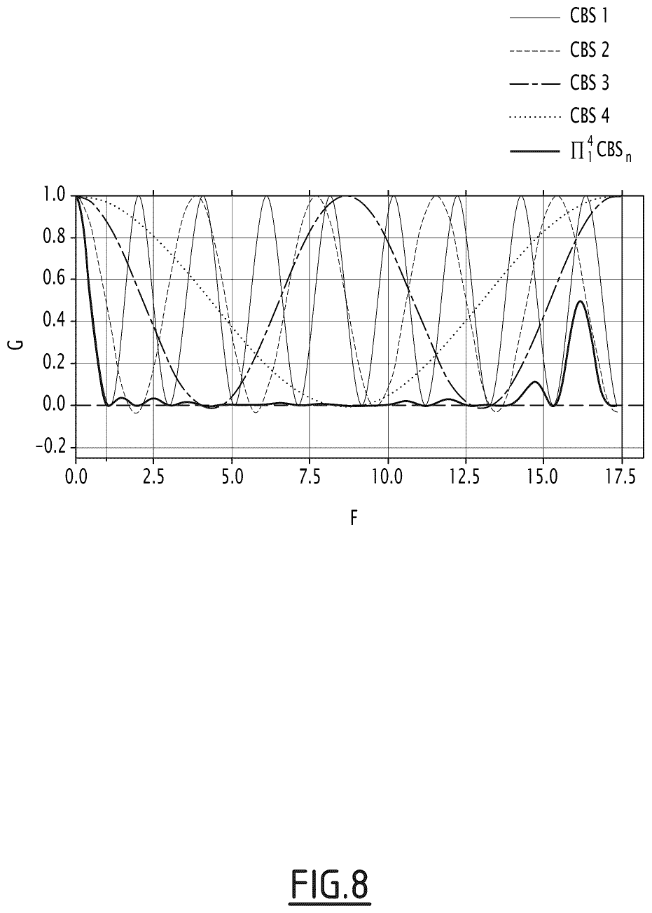

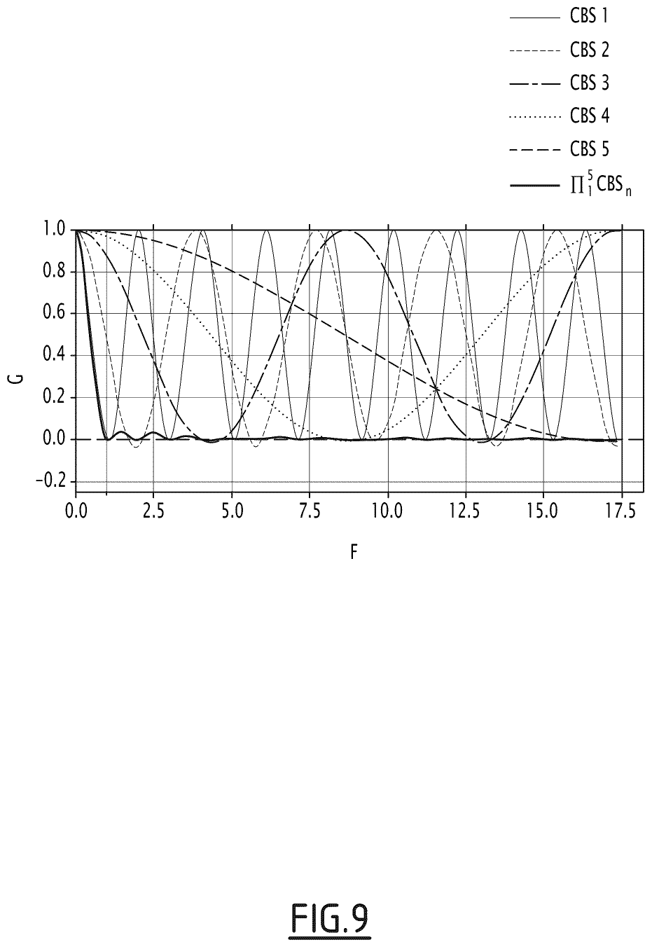

FIGS. 8 and 9 further illustrate individual responses of a CBS filter (CBS 4) and two CBS filters (CBS 4, CBS 5) respectively.

According to the explanations given above, the filters CBS 1, CBS 2, CBS 3 may form a first subset of the filters and the filters CBS 4, CBS 5 may form a second subset of the filters.

Thereby, as shown in FIGS. 8 and 9, the cut-off frequencies of the second subset are placed on the pass frequencies which remain at the output of the resulting function of the filters of the first subset. Thereof further emphasizes the advantage of the method, which makes it possible to have a plurality of clear cutoffs anywhere, in addition to the final low-pass function.

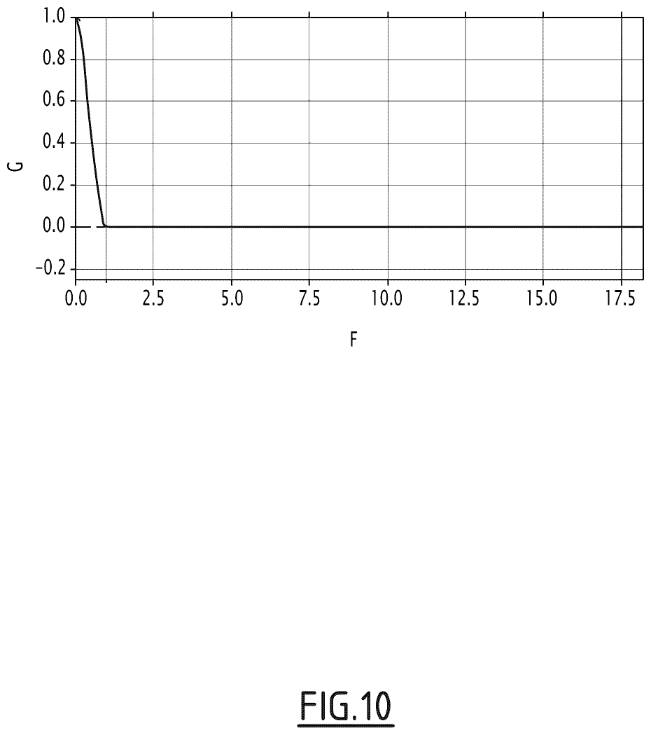

Finally, FIG. 10 illustrates a function resulting from an application of seven CBS filters. As may be seen in the figure, the function is almost everywhere equal to 0 except around 0 where the function is equal to 1.

In general, the number of CBS filters in the sequence of CBS filters is determined according to the required acquisition frequency range.

In one embodiment, the sequence of the CBS filters is followed by an application of a moving average to lead to a smoothing of the final result and a response closer to a Gaussian. Such addition smooths the result while preventing the need for too many CBS filters. In the previous example with the sequence of seven CBS filters, the application of a moving average may replace the application of two and three last CBS filters.

In this way, it may be understood that the present invention has a certain number of advantages.

First of all, the invention makes it possible to filter digital signals using a multitude of CBS filters, the computational resources of which needed for the operation thereof are low compared to a conventional FIR filtering.

More particularly, the proposed solution consists in aligning the CBS filters in series and possibly adding a moving average to have a result as close as possible to a Gaussian with a clear cut-off.

By means of the invention, it is possible to filter signals providing accurate results and in a cost-effective and economical way in terms of computational resources.

In addition, the invention makes it possible to filter signals in a way which is robust against disturbances and uncertainties.

Moreover, the invention guarantees fast results with a higher throughput than a conventional FIR filter.

The processing of a sample of the signal requires few operations, so even with a small number of coefficients, a large number of points may be processed within a short time. On the other hand, a conventional FIR filter with the same features would require many more operations, and to go as fast as possible, it would be necessary to have many more coefficients.

1. A finite impulse response filtering method, comprising:
acquiring a digital signal corresponding to an analog signal converted by an analog/digital converter;
processing the digital signal to transform the signal into a sum of a time-variable part and a time-constant part;
removing the variable part of the transformed digital signal so as to obtain a constant digital signal, by applying a sequence of a plurality of sinusoidal band-stop filters;
further processing the constant digital signal so as to obtain an amplitude of the signal; and
transmitting the amplitude to an application software.

2. The method according to claim 1, wherein the plurality of sinusoidal band-stop filters comprises between 2 and 20 sinusoidal band-stop filters.

3. The method according to claim 2, wherein the plurality of sinusoidal band-stop filters comprises between 4 and 10 sinusoidal band-stop filters.

4. The method according to claim 1, wherein the number of band-stop filters in the plurality of sinusoidal band-stop filters is chosen according to a frequency range of the digital signal.

5. The method according to claim 1, wherein each sinusoidal band-stop filter has a plurality of configuration parameters for configuring same.

6. The method according to claim 5, wherein each sinusoidal band-stop filter has two configuration parameters.

7. The method according to claim 5, wherein each sinusoidal band-stop filter has at least a first configuration parameter corresponding to a main cut-off frequency and a second configuration parameter corresponding to a spacing of the filter.

8. The method according to claim 5, wherein the plurality of sinusoidal band-stop filters have different configuration parameters.

9. The method according to claim 5, wherein the configuration parameters of the different sinusoidal band-stop filters are selected such that the cut-off frequencies of certain filters substantially correspond to the passband frequencies of the other filters.

10. The method according to claim 1, wherein said removing further comprises applying one or a plurality of moving averages to the digital signal resulting from the sequence of the plurality of sinusoidal band-stop filters.

11. The method according to claim 1, wherein the analog signal comes from an avionics sensor and wherein the application software is an avionics software.

12. The method according to claim 1, wherein said further processing comprises determining a phase of the constant signal.

13. A finite impulse response filtering device comprising:
an input module;
a processing module; and
an output module carrying out the method according to claim 1.
